(19) United States
(12) Patent Application Publication
(10) Pub. No.: US 2026/0079830 A1
(43) Pub. Date: Mar. 19, 2026

(54) MEMORY SYSTEM AND CONTROLLING METHOD

(71) Applicant: Kioxia Corporation, Tokyo (JP)

(72) Inventors: Kosuke SAKAI, Hiratsuka (JP); Yasuyuki USHIJIMA, Yokohama (JP); Katsuyuki SHIMADA, Ota (JP)

(73) Assignee: Kioxia Corporation, Tokyo (JP)

(21) Appl. No.: 19/068,066

(22) Filed: Mar. 3, 2025

(30) Foreign Application Priority Data
Sep. 18, 2024 (JP) 2024-160662

(51) Int. Cl. G06F 12/02; G11C 16/04; G11C 16/26

(52) U.S. Cl. CPC G06F 12/0246; G11C 16/0483; G11C 16/26

(57) ABSTRACT

A memory system includes an input data acquiring unit, a quantization range determining unit, a parameter setting unit, an estimating unit, and a voltage setting unit. The input data acquiring unit acquires input data indicating a relationship between the number of on-cells and a plurality of read voltages. The quantization range determining unit determines a quantization range of a shift value of the read voltages. The parameter setting unit sets a parameter of a quantized neural network. The estimating unit estimates a shift value of the read voltages from the input data with the quantized neural network using the parameter set by the parameter setting unit. The voltage setting unit sets a read voltage that is used during a read operation of a semiconductor storage device based on the shift value of the read voltages.

### CROSS-REFERENCE TO RELATED APPLICATION

This application is based upon and claims the benefit of priority from the prior Japanese Patent Applications No. 2024-160662, filed on Sep. 18, 2024; the entire contents of which are incorporated herein by reference.

### FIELD

Embodiments described herein relate to a memory system and a controlling method.

### BACKGROUND

A NAND flash memory is known as a semiconductor storage device.

### BRIEF DESCRIPTION OF THE DRAWINGS

FIG. 1 is a block diagram showing a schematic configuration of a memory system according to a first embodiment;

FIG. 2 is a block diagram showing a schematic configuration of a semiconductor storage device according to the first embodiment;

FIG. 3 is a circuit diagram showing a configuration of the semiconductor storage device according to the first embodiment;

FIG. 4 is a diagram showing an example of a threshold voltage distribution of a memory cell according to the first embodiment;

FIG. 5 is a diagram showing an example of a relationship between a shift value and an occurrence rate thereof of a read voltage according to the first embodiment;

FIG. 6 is a diagram showing an example of an estimation method of the shift value of the read voltage according to the first embodiment;

FIG. 7 is a diagram schematically showing a configuration of a quantized neural network according to the first embodiment;

FIG. 8 is a diagram showing a relationship among stress conditions, basic operation parameters, and quantization parameters according to the first embodiment;

FIG. 9 is a diagram showing an example of a relationship between the shift value and the occurrence rate thereof of the read voltage according to the first embodiment;

FIG. 10 is a flowchart showing procedures of processing related to determination of input data according to the first embodiment;

FIG. 11 is a block diagram showing a functional configuration of a memory controller according to the first embodiment;

FIG. 12 is a flowchart showing procedures of processing executed by the memory controller according to the first embodiment;

FIG. 13 is a flowchart showing procedures of processing executed by a memory controller according to a second embodiment;

FIG. 14 is a diagram showing an example of a relationship between a shift value and an occurrence rate thereof of a read voltage according to the second embodiment; and

FIG. 15 is a diagram showing a relationship among quantization ranges, basic operation parameters, and quantization parameters according to the second embodiment.

### DETAILED DESCRIPTION

In general, according to the embodiments, a memory system includes an input data acquiring unit, a quantization range determining unit, a parameter setting unit, an estimating unit, and a voltage setting unit. By having a semiconductor storage device read data using a plurality of read voltages, the input data acquiring unit acquires input data indicating a relationship between the number of on-cells being the number of memory cells that were turned on in the semiconductor storage device when the data was read and the plurality of read voltages. The quantization range determining unit determines a quantization range of a shift value of the read voltages that is estimated by a quantized neural network. The parameter setting unit sets a parameter of the quantized neural network based on the quantization range determined by the quantization range determining unit. The estimating unit estimates a shift value of the read voltages from the input data with the quantized neural network using the parameter set by the parameter setting unit. The voltage setting unit sets a read voltage that is used during a read operation of the semiconductor storage device based on the shift value of the read voltages.

Hereinafter, the embodiments will be described with reference to the drawings. In order to facilitate understanding of the description, same constituent elements in the respective drawings will be denoted by same reference signs whenever possible and redundant descriptions will not be repeated.

### 1. First Embodiment

A memory system according to a first embodiment will be described. A semiconductor storage device used in the memory system according to the present embodiment is a non-volatile storage device configured as a NAND flash memory.

### 1.1 Configuration of Memory System

First, a configuration of the memory system according to the present embodiment will be described.

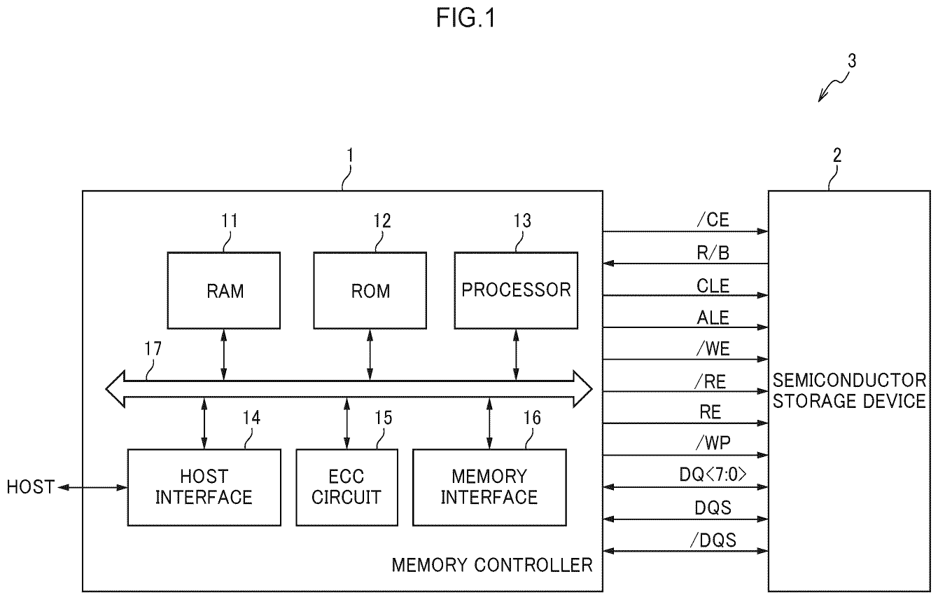

As shown in FIG. 1, a memory system 3 according to the present embodiment includes a memory controller 1 and a semiconductor storage device 2. The semiconductor storage device 2 is a non-volatile storage device configured as a NAND flash memory. The memory system 3 is capable of connecting to a host. For example, the host is an electronic device such as a personal computer or a mobile terminal.

The memory controller 1 controls writing of data to the semiconductor storage device 2 according to a write request from the host. In addition, the memory controller 1 controls reading of data from the semiconductor storage device 2 according to a read request from the host.

Between the memory controller 1 and the semiconductor storage device 2, a chip enable signal /CE, a ready busy signal R/B, a command latch enable signal CLE, an address latch enable signal ALE, a write enable signal /WE, read enable signals /RE and RE, a write protect signal /WP, a signal DQ <7:0>, and data strobe signals DQS and /DQS are transmitted and received.

The chip enable signal /CE is a signal to enable the semiconductor storage device 2. The ready busy signal /RB is a signal for indicating whether the semiconductor storage device 2 is in a ready state or a busy state. The “ready state” is, for example, a state in which instructions from the outside are accepted. The “busy state” is a state in which instructions from the outside are not accepted. The command latch enable signal CLE is a signal indicating that the signal DQ <7:0> is a command. The address latch enable signal ALE is a signal indicating that the signal DQ <7:0> is an address. The write enable signal /WE is a signal used to load received signals into the semiconductor storage device 2 and is asserted each time a command, address, or data is received by the memory controller 1. The read enable signals /RE and RE are signals used by the memory controller 1 to read data from the semiconductor storage device 2. The signal DQ <7:0> is the entity of data transmitted and received between the semiconductor storage device 2 and the memory controller 1 and includes a command, an address, and data. The data strobe signals DQS and /DQS are signals for controlling timings of input and output of the signal DQ <7:0>.

The memory controller 1 includes a RAM 11, a ROM 12, a processor 13, a host interface 14, an ECC circuit 15, and a memory interface 16. The components are connected to each other by an internal bus 17.

The host interface 14 outputs request, user data (write data), and the like received from the host to the internal bus 17. In addition, the host interface 14 transmits user data read from the semiconductor storage device 2, responses from the processor 13, and the like to the host.

The memory interface 16 controls, based on instructions from the processor 13, processing of writing user data and the like to the semiconductor storage device 2 and processing of reading user data and the like from the semiconductor storage device 2.

The processor 13 provides overall control of the memory controller 1. The processor 13 is a CPU, an MPU, or the like. When the processor 13 receives a request from the host via the host interface 14, the processor 13 performs control in accordance with the request. For example, according to a request from the host, the processor 13 instructs the memory interface 16 to write user data and parity to the semiconductor storage device 2. In addition, according to a request from the host, the processor 13 instructs the memory interface 16 to read user data and parity from the semiconductor storage device 2.

The processor 13 determines a storage area (memory area) on the semiconductor storage device 2 for user data accumulated in the RAM 11. The user data is stored in the RAM 11 via the internal bus 17. The processor 13 performs the determination of the memory area with respect to data in units of pages (page data) that are write units. Hereinafter, the user data to be stored in one page of the semiconductor storage device 2 is also referred to as “unit data”. Unit data is generally encoded and stored in the semiconductor storage device 2 as code words. In the present embodiment, encoding is not essential.

The processor 13 determines a memory area of the semiconductor storage device 2 to be a write destination for each piece of unit data. A physical address is assigned to the memory area of the semiconductor storage device 2. The processor 13 manages the memory area that is a write destination of unit data using the physical address. The processor 13 instructs the memory interface 16 to write user data to the semiconductor storage device 2 by designating the determined memory area (physical address). The processor 13 manages a correspondence between a logical address of the user data (logical address managed by the host) and a physical address. When the processor 13 receives a read request containing a logical address from the host, the processor 13 specifies the physical address corresponding to the logical address and instructs the memory interface 16 to read user data by designating the physical address.

The ECC circuit 15 encodes the user data stored in the RAM 11 and generates a code word. In addition, the ECC circuit 15 decodes a code word read from the semiconductor storage device 2.

The RAM 11 temporarily stores user data received from the host before storing the user data in the semiconductor storage device 2 or temporarily stores data read from the semiconductor storage device 2 before transmitting the data to the host. The RAM 11 is, for example a general-purpose memory such as an SRAM or a DRAM.

The ROM 12 is a semiconductor memory from which data can be read. The ROM 12 stores, for example, various kinds of data necessary for the processor 13 to operate.

When a write request is received from the host, the memory system 3 in FIG. 1 operates as follows. The processor 13 causes the RAM 11 to temporarily store data to be written. The processor 13 reads the data stored in the RAM 11 and inputs the data to the ECC circuit 15. The ECC circuit 15 encodes the input data and inputs the code word to the memory interface 16. The memory interface 16 writes the input cord word into the semiconductor storage device 2.

When a read request is received from the host, the memory system 3 in FIG. 1 operates as follows. The memory interface 16 inputs a code word read from the semiconductor storage device 2 to the ECC circuit 15. The ECC circuit 15 decodes the input cord word and stores the decoded data in the RAM 11. The processor 13 transmits the data stored in the RAM 11 to the host via the host interface 14.

### 1.2 Schematic Configuration of Semiconductor Storage Device

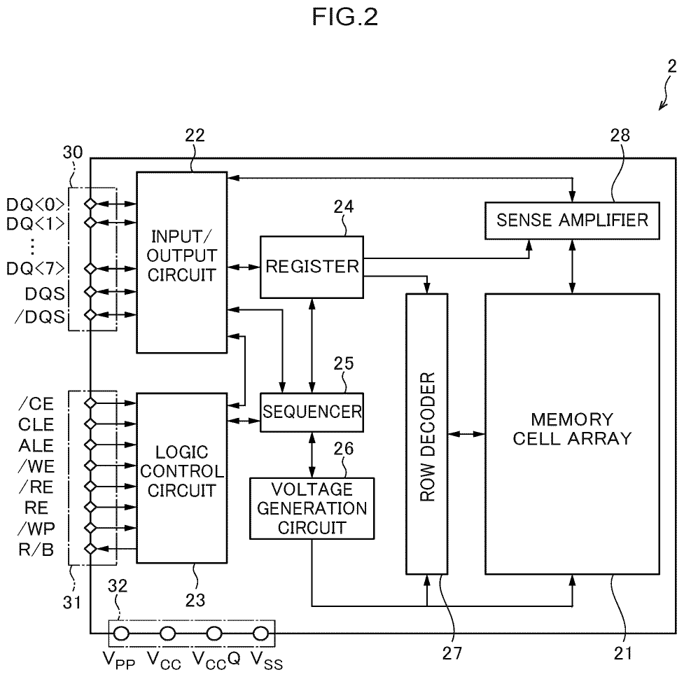

As shown in FIG. 2, the semiconductor storage device 2 includes a memory cell array 21, an input/output circuit 22, a logic control circuit 23, a register 24, a sequencer 25, a voltage generation circuit 26, a row decoder 27, a sense amplifier 28, a pad group for input/output 30, a pad group for logic control 31, and a terminal group for power input 32.

The memory cell array 21 is a portion that stores data. The memory cell array 21 is constituted of a plurality of memory cell transistors associated with a plurality of bit lines and a plurality of word lines.

The input/output circuit 22 transmits and receives the signal DQ <7:0> and the data strobe signals DQS, /DQS to and from the memory controller 1. In addition, the input/output circuit 22 transfers the commands and addresses in the signal DQ <7:0> to the register 24. Furthermore, the input/output circuit 22 transmits and receives write data and read data to and from the sense amplifier 28.

The logic control circuit 23 receives, from the memory controller 1, the chip enable signal /CE, the command latch enable signal CLE, the address latch enable signal ALE, the write enable signal /WE, the read enable signals /RE and RE, and the write protect signal /WP. In addition, the logic control circuit 23 transfers the ready busy signal /RB to the memory controller 1 and notifies a state of the semiconductor storage device 2 to the outside.

The register 24 temporarily holds various kinds of data. For example, the register 24 holds commands that instruct a write operation, a read operation, an erase operation, and the like. The commands are input from the memory controller 1 to the input/output circuit 22, subsequently transferred from the input/output circuit 22 to the register 24, and held by the register 24. In addition, the register 24 also holds addresses that correspond to the commands. The addresses are input from the memory controller 1 to the input/output circuit 22, subsequently transferred from the input/output circuit 22 to the register 24, and held by the register 24. Furthermore, the register 24 also holds status information that indicates an operating state of the semiconductor storage device 2. The status information is updated each time by the sequencer 25 according to the operating state of the memory cell array 21 and the like. The status information is output from the input/output circuit 22 to the memory controller 1 as a state signal upon request from the memory controller 1.

The sequencer 25 controls the operation of each unit including the memory cell array 21 based on control signals input to the input/output circuit 22 and the logic control circuit 23 from the memory controller 1.

The voltage generation circuit 26 is a portion that generates the voltages required for each of a write operation, a read operation, and an erase operation of data in the memory cell array 21. The voltages include, for example, voltages applied to the plurality of word lines and the plurality of bit lines in the memory cell array 21, respectively. The operation of the voltage generation circuit 26 is controlled by the sequencer 25.

The row decoder 27 is a circuit constituted of a switch group for applying voltages to the plurality of word lines of the memory cell array 21, respectively. The row decoder 27 receives a block address and a row address from the register 24, selects a block based on the block address, and selects a word line based on the row address. The row decoder 27 switches between opened/closed states of the switch group so that the voltage from the voltage generation circuit 26 is applied to the selected word line. The operation of the row decoder 27 is controlled by the sequencer 25.

The sense amplifier 28 is a circuit for adjusting the voltages applied to the bit lines of the memory cell array 21 or reading the voltages of the bit lines and converting the voltages into data. During read of data, the sense amplifier 28 acquires data read from a memory cell transistor of the memory cell array 21 to a bit line and transfers the acquired read data to the input/output circuit 22. During write of data, the sense amplifier 28 transfers data written via a bit line to a memory cell transistor. The operation of the sense amplifier 28 is controlled by the sequencer 25.

The pad group for input/output 30 is a portion provided with a plurality of terminals (pads) for performing transmission and reception of respective signals between the memory controller 1 and the input/output circuit 22. Each terminal is individually provided so as to correspond to each of the signal DQ <7:0> and the data strobe signals DQS, /DQS.

The pad group for logic control 31 is a portion provided with a plurality of terminals for performing transmission and reception of respective signals between the memory controller 1 and the logic control circuit 23. Each terminal is individually provided so as to correspond to each of the chip enable signal /CE, the command latch enable signal CLE, the address latch enable signal ALE, the write enable signal /WE, the read enable signals /RE and RE, the write protect signal /WP, and the ready busy signal /RB.

The terminal group for power input 32 is a portion provided with a plurality of terminals for receiving application of respective voltages necessary for operation of the semiconductor storage device 2. The voltages applied to the respective terminals include power supply voltages Vcc, VccQ, and Vpp and a ground voltage Vss. The power supply voltage Vcc is a circuit power supply voltage provided from outside as an operating power supply and is a voltage of, for example, around 2.5 V. The power supply voltage Vcc is a voltage for generating, for example, a voltage Vdd that is an internal power supply voltage of the semiconductor storage device 2. The power supply voltage Vdd is a voltage of, for example, around 1.5 V. The power supply voltage VccQ is a power supply voltage lower than the power supply voltage Vcc and is a voltage of, for example, 1.2 V. The power supply voltage VccQ is a power supply voltage for input/output used when transmitting and receiving signals between the memory controller 1 and the semiconductor storage device 2. The power supply voltage Vpp is a power supply voltage higher than the power supply voltage Vcc and is a voltage of, for example, 12 V.

### 1.3 Circuit Configuration of Memory Cell Array

Next, a circuit configuration of the memory cell array 21 will be described.

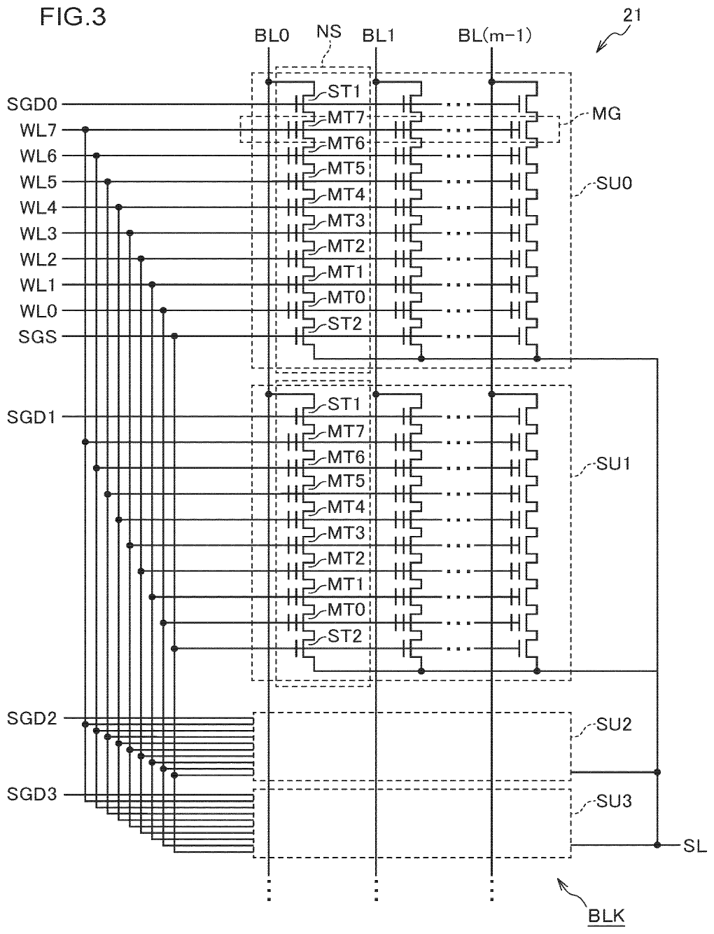

As shown in FIG. 3, the memory cell array 21 is constituted of a plurality of blocks BLK. Only one of the plurality of blocks BLK is shown in FIG. 3. Configurations of the other blocks BLK included in the memory cell array 21 are similar to the configuration shown in FIG. 3.

As shown in FIG. 3, for example, the block BLK includes four string units SU (SU0 to SU3). In addition, each string unit SU includes a plurality of NAND strings NS. For example, each of the NAND strings NS includes eight memory cell transistors MT (MT0 to MT7) and select transistors ST1 and ST2. Hereinafter, the memory cell transistors MT (MT0 to MT7) will be abbreviated as “memory cells MT (MT0 to MT7)”.

The memory cells MT are arranged between the select transistor ST1 and the select transistor ST2 so as to be connected in series. The memory cell MT7 on one end side is connected to a source of the select transistor ST1 and the memory cell MT0 on another end side is connected to a drain of the select transistor ST2.

Gates of the respective select transistors ST1 of the string units SU0 to SU3 are commonly connected to select gate lines SGD0 to SGD3. Gates of the select transistors ST2 are commonly connected to a same select gate line SGS among a plurality of string units SU in a same block BLK. Gates of the memory cells MT0 to MT7 in the same block BLK are each commonly connected to word lines WL0 to WL7. In other words, in contrast to the word lines WL0 to WL7 and the select gate line SGS being commonly provided among the plurality of string units SU0 to SU3 in the same block BLK, the selected gate lines SGD are independently provided for each of the string units SU0 to SU3 even in the same block BLK.

The memory cell array 21 is provided with m-number of bit lines BL (BL0, BL1, . . . , BL(m−1)). Reference character “m” denotes an integer corresponding to the number of NAND strings NS included in one string unit SU. A drain of the select transistor ST1 of each of the NAND strings NS is connected to a corresponding bit line BL. A source of the select transistor ST2 of each of the NAND strings NS is connected to a source line SL. The source line SL is common to the sources of the plurality of select transistors ST2 included in a block BLK.

Data stored in the plurality of memory cells MT in the same block BLK are collectively erased. On the other hand, read and write of data are collectively performed with respect to a plurality of memory cells MT which are connected to one word line WL and which belong to one string unit SU. Each memory cell can hold three bits of data consisting of an upper bit, a middle bit, and a lower bit. In other words, the semiconductor storage device 2 according to the present embodiment adopts an TLC method which stores 3-bit data in one memory cell MT as a method of writing data to the memory cells MT. Instead of such an aspect, an MLC method which stores 2-bit data in one memory cell MT may be adopted as the method of writing data to the memory cells MT. The number of bits of data to be stored in one memory cell MT is not particularly limited.

Note that in the following description, a set of 1-bit data to be stored in a plurality of memory cells MT which are connected to one word line WL and which belong to one string unit SU will be referred to as a “page”. In FIG. 3, a reference sign “MG” is attached to one of such sets constituted of a plurality of memory cells MT.

When data of three bits is to be stored in one memory cell MT as in the present embodiment, a set of a plurality of memory cells MT connected to a common word line WL in one string unit SU can store three pages' worth of data. In the data, a page constituted of a set of lower-order bit data will also be hereinafter referred to as a “lower-order page” and data in a lower-order page will also be hereinafter referred to as “lower-order page data”. In a similar manner, a page constituted of a set of middle-order bit data will also be hereinafter referred to as a “middle-order page” and data in a middle-order page will also be hereinafter referred to as “middle-order page data”. A page constituted of a set of higher-order bit data will also be hereinafter referred to as a “higher-order page” and data in a higher-order page will also be hereinafter referred to as “higher-order page data”.

### 1.4 Threshold Voltage Distribution of Memory Cell

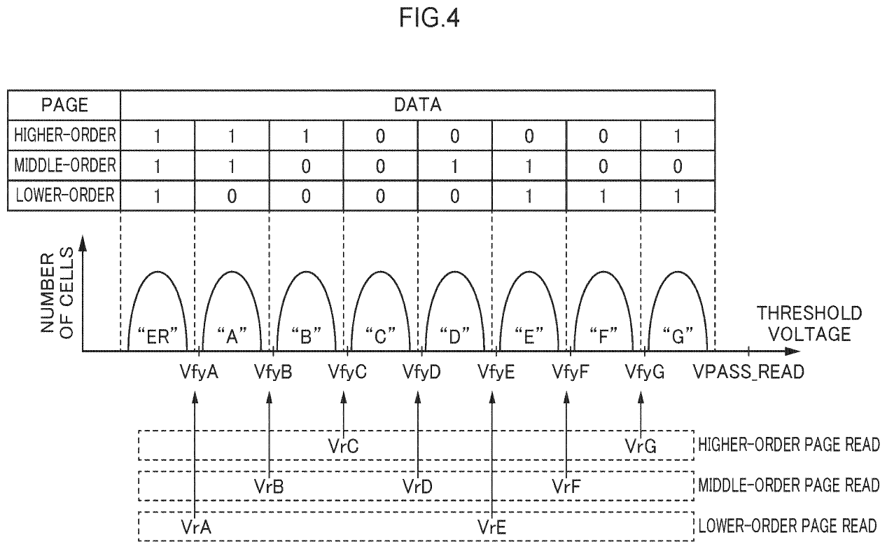

FIG. 4 is a diagram schematically showing a threshold voltage distribution and the like of the memory cells MT. A diagram in a middle section of FIG. 4 represents a correspondence relationship between a threshold voltage of the memory cells MT (axis of abscissa) and the number of memory cells MT (axis of ordinate).

When the TLC method is adopted as in the present embodiment, the plurality of memory cells MT form eight threshold voltage distributions as shown in the middle section of FIG. 4. The eight threshold voltage distributions (write levels) will be referred to, in a descending order to threshold voltage, an “ER” level, an “A” level, a “B” level, a “C” level, a “D” level, an “E” level, an “F” level, and a “G” level. A table in an upper section of FIG. 4 represents examples of 3-bit data assigned so as to correspond to each of the threshold voltage levels.

As described above, the threshold voltage of a memory cell MT in the present embodiment can assume one of eight candidate levels set in advance and data is assigned as described above for each candidate level.

A read voltage used in a read operation is set between adjacent threshold voltage distributions, respectively. A “read voltage” is a voltage applied to the word line WL that connects to the memory cell MT to be read or, in other words, a selected word line during a read operation. In the read operation, data is determined based on a determination result of whether or not the threshold voltage of the memory cell MT to be read is higher than an applied read voltage. For example, as schematically shown in a diagram in a lower section in FIG. 4, a read voltage VrA for determining which of the level “ER” and the level “A” the threshold voltage of the memory cell MT belongs is set between a maximum threshold voltage in the level “ER” and a minimum threshold voltage in the level “A”. Other read voltages VrB, VrC, VrD, VrE, VrF, and VrG are set in a similar manner as the read voltage VrA.

A read pass voltage VPASS_READ is set to a voltage that is higher than a maximum threshold voltage of a highest threshold voltage distribution (for example, level “G”). The memory cell MT in which the read pass voltage VPASS_READ is applied to a gate thereof is turned on regardless of the data to be stored.

When the data allocation as described above is applied, one page data of the lower-order bit (lower-order page data) can be determined by a read result using the read voltages VrA and VrE in the read operation. One page data of the middle-order bit (middle-order page data) can be determined by a read result using the read voltages VrB, VrD, and VrF. One page data of the higher-order bit (higher-order page data) can be determined by a read result using the read voltages VrC and VrG.

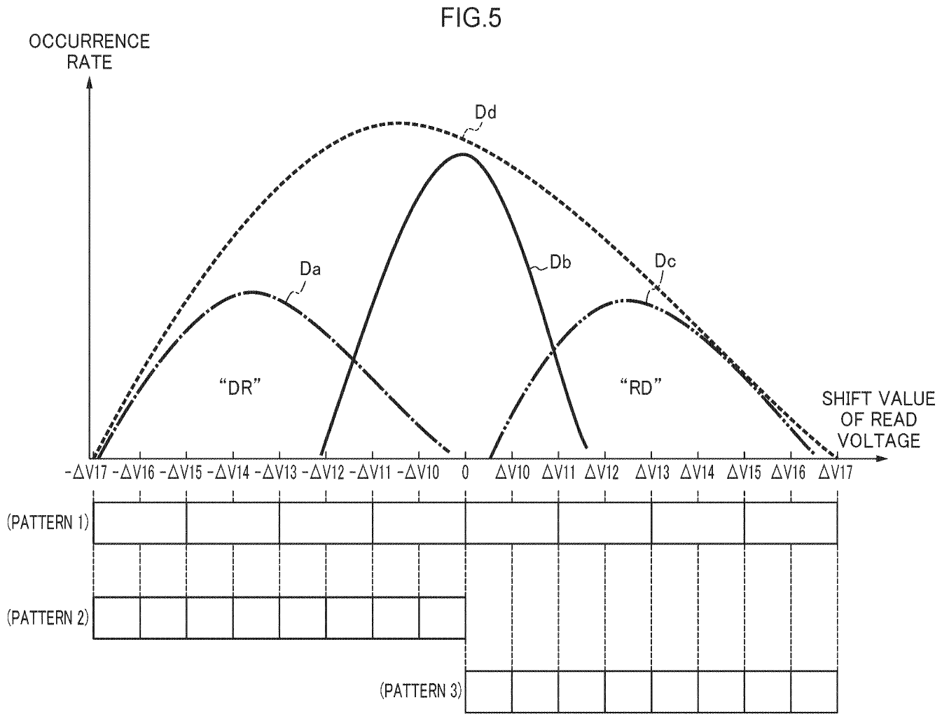

Such read voltages change depending on stress applied to the memory cells MT. FIG. 5 shows a distribution of shift values of read voltages due to changing stress conditions. A shift value of read voltages is an amount of deviation between an optimal read voltage with respect to a present threshold voltage distribution of the memory cells MT and read voltages set in advance. Note that FIG. 5 only shows a distribution of a shift value of one read voltage (for example, VrA) among the plurality of read voltages shown in FIG. 4.

For example, in a situation where a strong stress is not applied to the memory cells MT or, in other words, in an ideal situation, the read voltage hardly changes. Therefore, in such a situation, the shift value of the read voltage exhibits a distribution Db as indicated by a solid line in FIG. 5. Note that a stress condition under which the distribution Db indicated by the solid line in FIG. 5 is formed will be hereinafter referred to as an ideal stress condition for the sake of convenience.

In contrast, when a same memory cell MT is subjected to a stress of repeated data reads, the read voltage shifts to a higher voltage side. Therefore, in such a situation, the shift value of the read voltage exhibits a distribution indicated by a dashed-two dotted line in FIG. 5 or, in other words, a distribution Dc representing a transition to a higher voltage side than the ideal distribution indicated by the solid line. Such a stress condition is referred to as a Read Disturb condition.

On the other hand, when a same memory cell MT is subjected to a stress of having data written thereto and subsequently left in that state for a long period of time, the read voltage shifts to a lower voltage side. Therefore, in such a situation, the shift value of the read voltage exhibits a distribution indicated by a dashed-dotted line in FIG. 5 or, in other words, a distribution Da representing a transition to a lower voltage side than the ideal distribution indicated by the solid line. Such a stress condition is referred to as a Data Retention condition.

Note that in FIG. 5, a distribution of shift values of read voltages with respect to all stress conditions is indicated by a dashed line Dd.

As described above, since the shift value of read voltages changes according to stress conditions, the read voltages must be changed appropriately in such a memory system 3. In the memory system 3, for example, when the memory controller 1 is unable to read data from the semiconductor storage device 2 during a read operation of the semiconductor storage device 2 or unable to recover data by error correction, the memory controller 1 determines that an optimal read voltage may have changed and executes estimation processing of a read voltage. Alternatively, the memory controller 1 executes processing of estimating a shift value of a read voltage during patrol processing of the semiconductor storage device 2. Patrol processing is processing of regularly or irregularly performing read operations to read data stored in the semiconductor storage device 2 with a small number of error bits. The patrol processing includes update patrol processing of updating the read voltage used when reading data in order to reduce errors contained in the data read from the memory cell MT to be patrolled. For example, the processing of estimating the shift value of a read voltage is used to update the read voltage of a memory cell MT in the update patrol processing.

On the other hand, in the memory system 3 according to the present embodiment, an optimal read voltage of a memory cell MT is estimated using a neural network. In this case, if an operation of the neural network is performed by a floating-point operation, although operational precision can be ensured, there are concerns about an increase in memory capacity, an increase in latency, and an increase in circuit size. In consideration thereof, in the memory system 3 according to the present embodiment, a shift value of a read voltage is estimated using a so-called quantized neural network in which operations are performed by an integer operation. However, when using a quantized neural network, there is a trade-off relationship between the number of quantized bits and operational accuracy.

For example, when the shift value of a read voltage changes according to stress conditions as shown in FIG. 5, a quantization range of the shift value of the read voltage must be set to a range from “−ΔV17” to “ΔV17” in order to enable the shift value of the read voltage to be estimated under all stress conditions. In this case, if the number of quantization bits of the quantized neural network is set to 3 bits, the shift value of the read voltage is to be estimated with 3 bits in the range from “−ΔV17” to “ΔV17” as shown in a Pattern 1 in FIG. 5. In other words, the shift value of the read voltage is to be estimated in eight divisions in the range from “−ΔV17” to “ΔV17”. Note that a range that can be expressed by one bit is represented by a square frame. If the shift value of the read voltage is estimated in this manner, for example, when the memory cell MT is stressed under the DR condition, since the shift value of the read voltage can only assume a range from “−ΔV17” to “0”, the shift value of the read voltage can only be effectively estimated with an accuracy of 2 bits. Therefore, there is a risk that estimation accuracy of the shift value of a read voltage cannot be secured.

In consideration thereof, in the memory system 3 according to the present embodiment, a determination is made as to which of the distributions Da to Dc shown in FIG. 5 the distribution of the shift value of the read voltage corresponds to and a quantization range of the quantized neural network is changed according to a result of the determination. For example, when the memory system 3 determines that the shift value of the read voltage has the distribution Da, the memory system 3 sets the quantization range of the quantized neural network to a range from “−ΔV17” to “0” as indicated by a Pattern 2 in FIG. 5. Accordingly, when the memory cell MT is stressed under the DR condition, the shift value of the read voltage can be estimated with an accuracy of 3 bits. In addition, when the memory system 3 determines that the shift value of the read voltage has the distribution Dc, the memory system 3 sets the quantization range of the quantized neural network to a range from “0” to “ΔV17” as indicated by a Pattern 3 in FIG. 5. Accordingly, even when the memory cell MT is stressed under the RD condition, the shift value of the read voltage can be estimated with an accuracy of 3 bits. In this manner, in the memory system 3 according to the present embodiment, 3-bit operational accuracy is maintained by changing the quantization range of the quantized neural network according to stress conditions.

### 1.5 Principle of Estimation of Shift Value of Read Voltage

Before describing a configuration for realizing the estimation of a shift value of a read voltage as described above, a principle of the estimation of the shift value of a read voltage will be described.

The memory system 3 according to the present embodiment causes the semiconductor storage device 2 to read data using a plurality of different read voltages and estimates a shift value of the read voltages using the number of on-cells being the number of memory cells MT that are in the on state at that time.

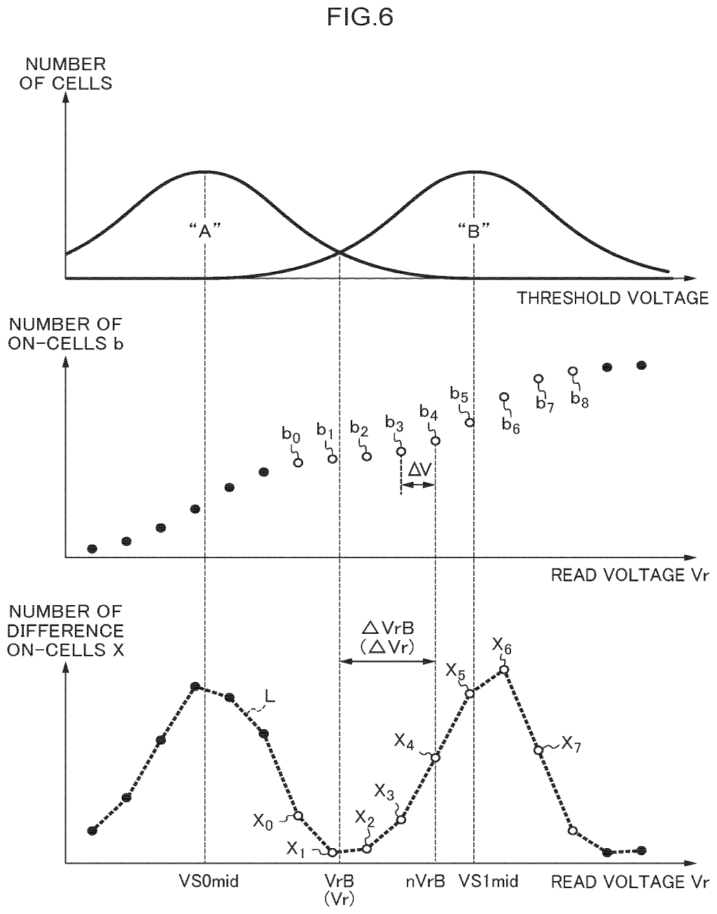

A graph in the upper section of FIG. 6 shows, as one example, two threshold voltage distributions corresponding to level “A” and level “B”. A graph in the middle section of FIG. 6 shows a relationship between a read voltage Vr and the number of on-cells b. The respective graphs of the upper section and a lower section of FIG. 6 exemplify a case where an optimal read voltage corresponding to level “A” and level “B” or, in other words, a read voltage that minimizes an overlap between a threshold voltage distribution belonging to level “A” and a threshold voltage distribution belonging to level “B” makes a transition of exactly ΔVrB (<0) from nVrB.

As shown in the graph in the middle section of FIG. 6, when the read voltage Vr is gradually increases, the number of on-cells b abruptly increases at a voltage that is slightly higher than a voltage VS0mid being a mode of level “A”. In this case, the mode is a voltage at which the distribution probability of the threshold voltage reaches its maximum in the graph in the upper section of FIG. 6. When the read voltage Vr is further increased, the rate of increase of the number of on-cells b decreases. When the threshold voltage distribution belonging to level “A” overlaps with the threshold voltage distribution belonging to level “B” as shown in the graph in the upper section of FIG. 6, since the rate of increase of the number of on-cells b is larger than zero, the number of on-cells b increases slightly with an increase in the read voltage Vr. Note that when the threshold voltage distribution belonging to level “A” does not overlap with the threshold voltage distribution belonging to level “B”, since the rate of increase of the number of on-cells b is zero, the number of on-cells b is maintained at a predetermined value even if the read voltage Vr increases. The number of on-cells b increases once again as the read voltage Vr further increases, and the number of on-cells b abruptly increases at a voltage that is slightly higher than a voltage VS1mid being a mode of level “B”.

From such a transition of the number of on-cells b, the read voltage VrB that minimizes an overlap of the threshold voltage distributions between the two levels or, in other words, the read voltage VrB that corresponds to an intersection of the threshold voltage distributions of two states can be estimated by, for example, the following procedure.

First, by performing read processing using a predetermined read voltage nVrB, the number of on-cells b₄ corresponding to the predetermined read voltage nVrB is acquired. The predetermined read voltage nVrB is a predetermined voltage that is set in advance so as to be used as the read voltage VrB shown in FIG. 4. Next, by performing a read operation while lowering the read voltage at intervals of a predetermined voltage ΔV from nVrB, the numbers of on-cells b₃, b₂, b₁, and b₀ respectively corresponding to “nVrB−ΔV”, “nVrB−2×ΔV”, “nVrB−3×ΔV”, and “nVrB−4×ΔV” are acquired. In addition, by performing a read operation while increasing the read voltage at intervals of the predetermined voltage ΔV from nVrB, the numbers of on-cells b₅, b₆, b₇, and b₈ respectively corresponding to “nVrB+ΔV”, “nVrB+2×ΔV”, “nVrB+3×ΔV”, and “nVrB+4×ΔV” are acquired. In this manner, the numbers of on-cells b₀ to b₈ preceding and following the predetermined read voltage nVrB are acquired.

Next, the number of difference on-cells Xₖ is computed based on Expression f1 below from the acquired numbers of on-cells b₀ to b₈. Note that in Expression f1, k=0, 1, 2, . . . , 7.

Xₖ=bₖ₊₁−bₖ (f1)

The graph in the lower section of FIG. 6 shows a relationship between the read voltage Vr and the number of difference on-cells X. In the graph in the lower section of FIG. 6, straight lines respectively connecting the numbers of difference on-cells X₀ to X₇ are indicated by dashed lines L. From the graph in the lower section of FIG. 6, the optimal read voltage VrB corresponding to level “A” and level “B” can be estimated. Specifically, by considering the read voltage at which the dashed line L in the graph in the lower section of FIG. 6 assumes a minimum value to be the read voltage that minimizes the overlap between the threshold voltage distribution belonging to level “A” overlaps and the threshold voltage distribution belonging to level “B”, the read voltage can be set to a read voltage VrB that corresponds to level “A” and level “B”. Note that, hereinafter, a shift value of the optimal read voltage VrB from the predetermined read voltage nVrB is expressed by “ΔVr”.

While a method of setting the read voltage VrB corresponding to level “A” and level “B” has been described so far, other read voltages VrA, VrC, . . . , VrG can be set to optimal values in a similar manner by performing similar processing with respect to the other read voltages VrA, VrC, . . . , VrG.

### 1.6 Configuration of Quantized Neural Network

Next, a configuration of a quantized neural network that utilizes the principle described above will be described.

In the present embodiment, a portion of computing the shift value ΔVr of a read voltage from the number of difference on-cells X and the predetermined read voltage nVr in the principle described above is to be performed by the quantized neural network.

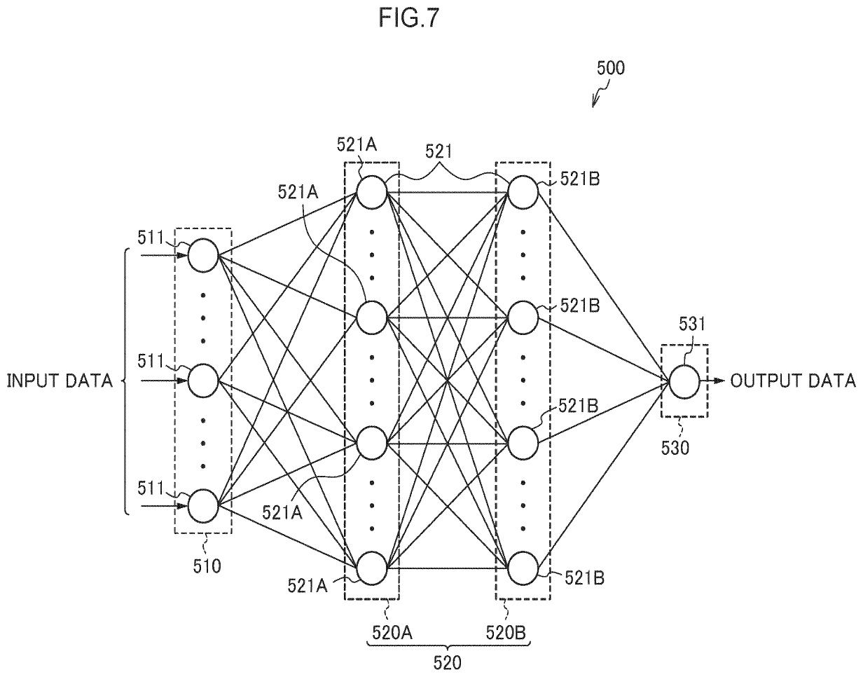

As shown in FIG. 7, a quantized neural network 500 includes an input layer 510, an intermediate layer 520, and an output layer 530.

The input layer 510 receives predetermined input data. The input layer 510 includes a plurality of operational units (also referred to as neurons or neuron units) 511. Note that the operational units 511 may be dedicated apparatuses or circuits and processing of the operational units 511 may be realized by a processor by executing a program. Hereinafter, a similar configuration will be described as operational units. In the input layer 510, each operational unit 511 subjects the input data to any processing (for example, linear transformation or addition of auxiliary data) to transform the input data, and transmits the transformed data to the intermediate layer 520.

The intermediate layer 520 (520A and 520B) executes various kinds of operational processing with respect to the data from the input layer 510.

The intermediate layer 520 includes a plurality of operational units 521 (521A and 521B). In the intermediate layer 520, each operational unit 521 performs operational processing (for example, sum-of-product processing) using a predetermined parameter (for example, a weight w) on the supplied data (hereafter, referred to as interlayer input data for the sake of distinction). For example, each operational unit 521 executes sum-of-product processing using mutually different parameters with respect to supplied data.

The intermediate layer 520 may be hierarchical. In this case, the intermediate layer 520 includes at least two layers (first intermediate layer 520A and second intermediate layer 520B). The first intermediate layer 520A includes a plurality of operational units 521A and the second intermediate layer 520B includes a plurality of operational units 521B.

Each operational unit 521A of the first intermediate layer 520A executes predetermined operational processing with respect to interlayer input data that is a processing result of the input layer 510. Each operational unit 521A transmits an operation result to each operational unit 521B of the second intermediate layer 520B. Each operational unit 521B of the second intermediate layer 520B executes predetermined operational processing with respect to interlayer input data that is an operation result of each operational unit 521A. Each operational unit 521B transmits an operation result to the output layer 530.

In this manner, when the intermediate layer 520 has a hierarchical structure, performance of inference and learning/training by the quantized neural network 500 may improve. Note that the number of layers of the intermediate layer 520 may be three or more or may be one. One intermediate layer may be configured to include a combination of processing of any kind such as sum-of-product processing, pooling processing, normalization processing, and activation processing.

The output layer 530 receives results of various kinds of operational processing executed by the respective operational units 521 of the intermediate layer 520 and executes various kinds of processing.

The output layer 530 includes an operational unit 531. By executing operational processing using a predetermined parameter with respect to interlayer input data that is an operation result of the plurality of operational units 521B, the operational unit 531 outputs data of the operation result.

Note that, hereinafter, a parameter used by the intermediate layer 520 and the output layer 530 will be referred to as a basic operation parameter Pb.

On the other hand, in a general neural network, various parameters, interlayer input data, and the like are expressed in 16-bit to 32-bit floating points. In contrast, the quantized neural network 500 according to the present embodiment reduces capacity, latency, and circuit size by expressing various parameters, interlayer input data, and the like in 1-bit to 8-bit integers. In the quantized neural network 500 according to the present embodiment, a case where the output layer 530 outputs data of an operation result with 3-bit accuracy will be described as an example.

In addition, the quantized neural network 500 uses a quantization scale S and a zero point Z as parameters to adjust the data output from the output layer 530. The quantization scale S is a parameter indicating a resolution of a value after quantization and is a real-number parameter for adjusting scales between a real number r before quantization and an integer q after quantization. The zero point Z is an integer value assumed after quantization by a value that had been a real value and zero before quantization and is an offset in order to adjust the integer q after quantization so that the real number r before quantization is represented by zero. The real number r before quantization, the integer q after quantization, the quantization scale S, and the zero point Z satisfy the following Expression f2.

r=S(q−Z) (f2)

Note that since the quantization scale S and the zero point Z used in the quantized neural network 500 are well-known technical contents, a detailed description thereof will be omitted. Hereinafter, the quantization scale S and the zero point Z will also be referred to as quantization parameters Pq.

In the quantized neural network 500 according to the present embodiment, the number of difference on-cells X is input as input data.

A predetermined read voltage nVr is any of a predetermined read voltage nVrA corresponding to the read voltage VrA, a predetermined read voltage nVrB corresponding to the read voltage VrB, a predetermined read voltage nVrC corresponding to the read voltage VrC, a predetermined read voltage nVrD corresponding to the read voltage VrD, a predetermined read voltage nVrE corresponding to the read voltage VrE, a predetermined read voltage nVrF corresponding to the read voltage VrF, and a predetermined read voltage nVrG corresponding to the read voltage VrG. The predetermined read voltage nVr is stored in advance in the ROM 12 of the memory controller 1.

The number of difference on-cells X is the numbers of difference on-cells X respectively corresponding to a plurality of read voltages preceding and following the predetermined read voltage nVr as a reference. For example, when data such as that shown in the graph in the lower section of FIG. 6 has been obtained, the numbers of difference on-cells X₀ to X₇ are input to the input layer 510.

In addition, in the quantized neural network 500 according to the present embodiment, the output layer 530 outputs a shift value ΔVr of a read voltage. For example, when data such as that shown in the graph in the lower section of FIG. 6 has been obtained, the output layer 530 outputs a shift value ΔVrB of a read voltage.

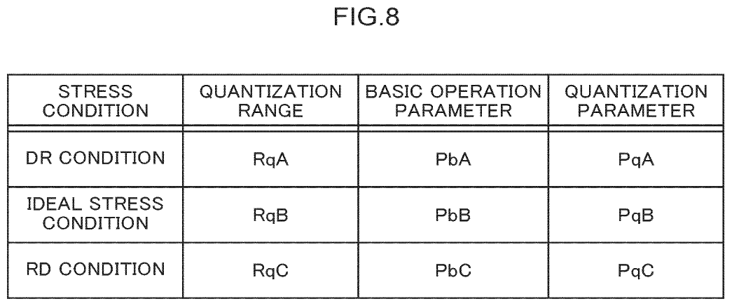

On the other hand, in consideration of the fact that a distribution area of a shift value of a read voltage changes as shown in FIG. 5 according to stress conditions, the quantized neural network 500 according to the present embodiment uses basic operation parameters PbA, PbB, and PbC and quantization parameters PqA, PqB, and PqC according to stress condition as shown in FIG. 8.

Specifically, in the memory system 3 according to the present embodiment, a plurality of pieces of input/output training data corresponding to the ideal stress condition, a plurality of pieces of input/output training data corresponding to the RD condition, and a plurality of pieces of input/output training data corresponding to the DR condition have been prepared through experiments and the like in order to train the quantized neural network 500.

Based on the training data, first, a quantization range corresponding to each stress condition is set and, at the same time, a boundary condition of each stress condition is set.

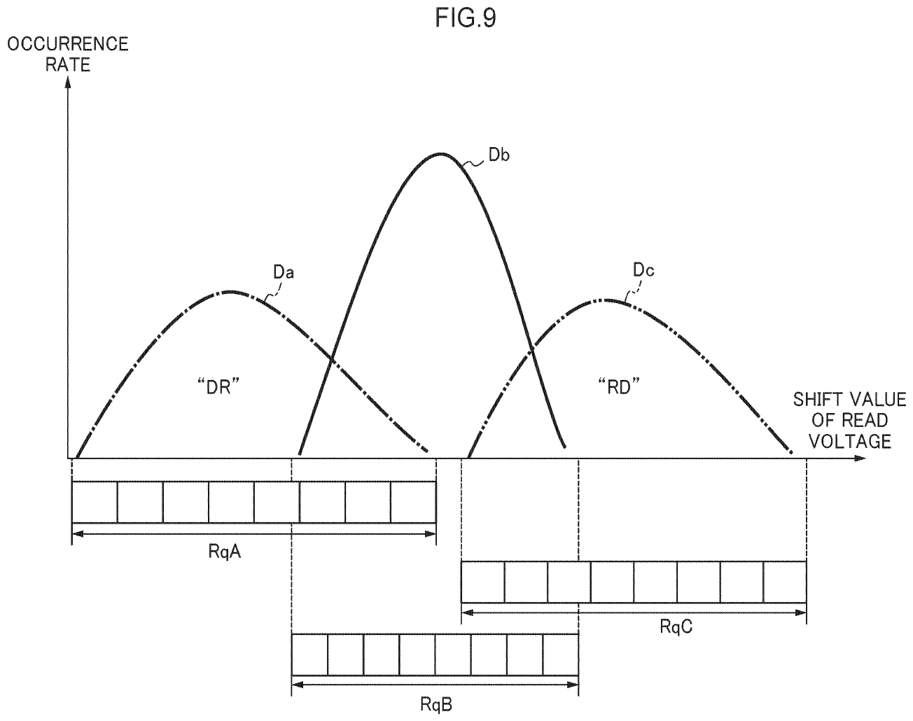

For example, by analyzing the output data contained in the plurality of pieces of training data corresponding to the ideal stress condition, a range that the plurality of pieces of output data can take or, in other words, a range that the shift value ΔVr of the read voltage corresponding to the ideal stress condition can take can be obtained, for example, as a range RqB shown in FIG. 9. Due to the range RqB being used as the quantization range corresponding to the ideal stress condition, a quantization parameter PqB or, more specifically, a quantization scale SB and a zero point ZB are set based on the quantization range RqB. For example, when the quantization range RqB is estimated with 3-bit accuracy, the quantization scale SB is set to a voltage width that enables the quantization range RqB to be divided into eight equal parts as shown in FIG. 9.

In addition, the basic operation parameter PbB corresponding to the ideal stress condition is obtained by training the quantized neural network 500 using the plurality of pieces of input/output training data corresponding to the ideal stress condition.

The quantization parameter PqB and the basic operation parameter PbB corresponding to the ideal stress condition are acquired as described above. A quantization range RqA, a quantization parameter PqA, and a basic operation parameter PbA corresponding to the DR condition and a quantization range RqC, a quantization parameter PqC, and a basic operation parameter PbC corresponding to the RD condition are acquired using similar methods.

Note that FIG. 8 describes a correspondence relationship between each stress condition and the quantization ranges shown in FIG. 9.

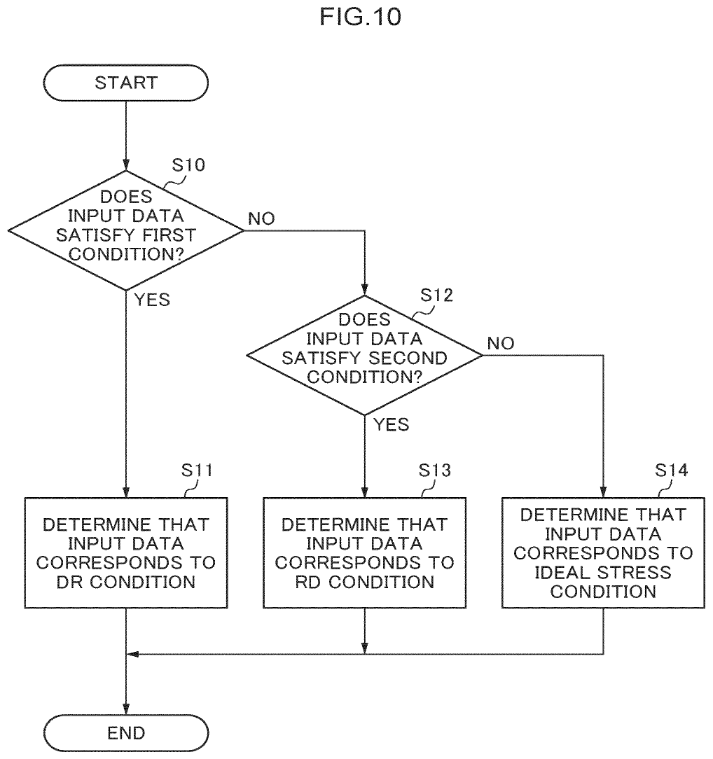

On the other hand, in order to switch the basic operation parameter Pb and the quantization parameter Pq according to the stress condition, it is necessary to determine which of the three stress conditions the actual input data corresponds to. To this end, in the present embodiment, boundary conditions for determining which of the three stress conditions the input data corresponds to are set in advance by using the training data for each stress condition. For example, the boundary conditions are set as shown in FIG. 10.

First, a determination is made as to whether or not the actual input data satisfies a first condition (step S10). The first condition is a condition that enables a determination that the actual input data corresponds to the DR condition and does not correspond to the other stress conditions to be made. As the first condition, for example, a condition represented by Expression f3 below using the numbers of difference on-cells X₀ to X₇ contained in input data can be used.

Xᵢ>T_{A} (f3)

Note that in Expression f3, i is an integer satisfying “0≤i≤7”. T_{A} is set to a value that enables a determination that the numbers of difference on-cells X₀ to X₇ correspond to the DR condition and do not correspond to the other stress conditions to be made. T_{A} is obtained in advance by using training data for each stress condition. In the present embodiment, the first condition is an example of a boundary condition.

When the actual input data satisfies the first condition (step S10: YES), a determination is made that the actual input data corresponds to the DR condition (step S11).

When the actual input data does not satisfy the first condition (step S10: NO), a determination is made as to whether or not the actual input data satisfies a second condition (step S12). The second condition is a condition that enables a determination that the numbers of difference on-cells X₀ to X₇ are input data that corresponds to the RD condition and are not input data that corresponds to the other stress conditions to be made. As the second condition, for example, a condition represented by Expression f4 below using the numbers of difference on-cells X₀ to X₇ contained in input data can be used.

Xⱼ>T_{B} (f4)

Note that in Expression f4, j is an integer satisfying “0≤j≤7”. T_{B} is set to a value that enables a determination that the numbers of difference on-cells X₀ to X₇ correspond to the RD condition and do not correspond to the other stress conditions to be made. T_{B} is obtained in advance by using training data for each stress condition. In the present embodiment, the second condition is an example of a boundary condition.

When the actual input data satisfies the second condition (step S12: YES), a determination is made that the actual input data corresponds to the RD condition (step S13).

When the actual input data does not satisfy the second condition (step S12: NO), a determination is made that the actual input data corresponds to the ideal stress condition (step S14).

In the quantized neural network 500 according to the present embodiment, after a determination as to which of the three stress conditions the input data containing the number of difference on-cells X corresponds to is made based on the processing shown in FIG. 10, the quantization parameter Pq and the basic operation parameter Pb are selected based on a determination result thereof. For example, when it is determined that the input data corresponds to the DR condition based on the processing shown in FIG. 10, the basic operation parameter PbA and the quantization parameter PqA shown in FIG. 9 are selected. In addition, the quantized neural network 500 performs an operation of the shift value ΔVr of the read voltage using the basic operation parameter PbA and the quantization parameter PqA.

### 1.7 Configuration of Memory Controller

Next, a configuration of the memory controller 1 for setting an optimal read voltage of the memory cells MT using the quantized neural network 500 described above will be described in specific terms.

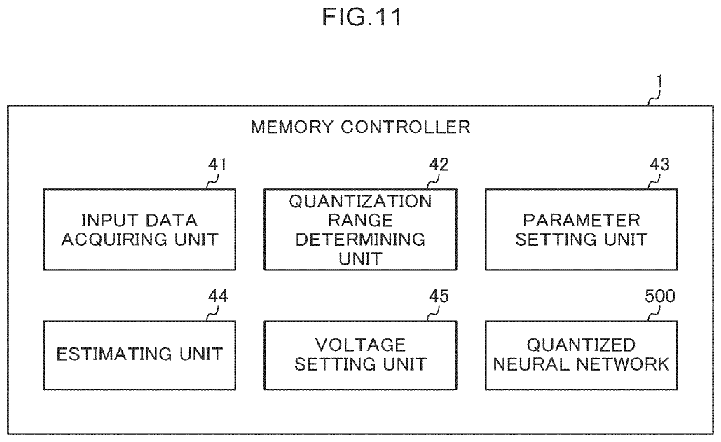

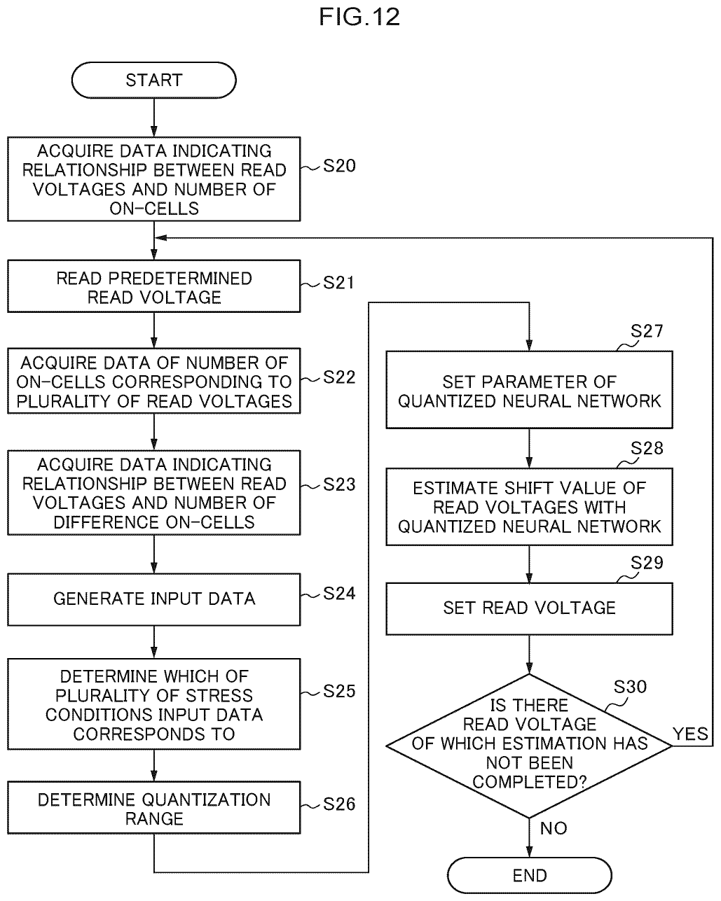

As shown in FIG. 11, the memory controller 1 includes an input data acquiring unit 41, a quantization range determining unit 42, a parameter setting unit 43, an estimating unit 44, a voltage setting unit 45, and the quantized neural network 500. These functions are realized by any of hardware such as electronic circuits included in the memory controller 1, firmware, and software, or a combination of two or more of hardware, firmware, and software. For example, the quantized neural network 500 is stored in the ROM 12. In addition, functions of the input data acquiring unit 41, the quantization range determining unit 42, the parameter setting unit 43, the estimating unit 44, and the voltage setting unit 45 are realized when a program stored in the ROM 12 and readable by a computer is deployed on the RAM 11 and executed by the processor 13. In this case, the RAM 11 and the ROM 12 represent examples of a storage medium. Hereinafter, operation examples of the input data acquiring unit 41, the quantization range determining unit 42, the parameter setting unit 43, the estimating unit 44, and the voltage setting unit 45 will be described with reference to FIG. 12. FIG. 12 is a flowchart showing a procedure of estimation processing of a read voltage executed by the memory controller 1 when data cannot be recovered by error correction or during the patrol processing.

As shown in FIG. 12, in the estimation processing of a read voltage, first, the input data acquiring unit 41 acquires data indicating a relationship between a read voltage Vr and the number of on-cells b as indicated by the graph in the middle section of FIG. 6 (step S20). For example, the input data acquiring unit 41 sequentially acquires data of the number of on-cells b corresponding to each read voltage Vr by increasing the read voltage Vr from the ground voltage Vss to a read pass voltage VPASS_READ at intervals of a predetermined voltage ΔV.

Next, the input data acquiring unit 41 reads one of a plurality of predetermined read voltages nVr of the memory cells MT from the ROM 12 (step S21). Hereinafter, as an example, a case where the input data acquiring unit 41 reads the predetermined read voltage nVrB corresponding to level “A” and level “B” will be described.

Next, based on the predetermined read voltage nVrB read in step S21, the input data acquiring unit 41 acquires data of the number of on-cells corresponding to a plurality of read voltages near the predetermined read voltage nVrB from the data acquired in step S20 (step S22). For example, as shown in the graph in the middle section of FIG. 6, the input data acquiring unit 41 acquires the number of on-cells b₄ corresponding to the predetermined read voltage nVrB, the numbers of on-cells b₀ to b₃ corresponding to a plurality of read voltages lower than the predetermined read voltage nVrB, and the numbers of on-cells b₅ to b₈ corresponding to a plurality of read voltages higher than the predetermined read voltage nVrB.

Next, by computing the numbers of difference on-cells X₀ to X₇ using the Expression f1 described above from the plurality of numbers of on-cells b₀ to b₈ acquired in the processing of step S22, the input data acquiring unit 41 acquires data indicating a relationship between the read voltage Vr and the numbers of difference on-cells X₀ to X₇ as shown in the graph in the lower section of FIG. 6 (step S23).

Next, the input data acquiring unit 41 generates input data of the quantized neural network 500 from the data indicating the relationship between the read voltage Vr and the numbers of difference on-cells X₀ to X₇ acquired in the processing of step S23 (step S24).

Next, by executing the processing shown in FIG. 10 using the actual input data generated in the processing of step S24, the quantization range determining unit 42 determines which of the three stress conditions the actual input data corresponds to (step S25). Hereinafter, a case where the actual input data corresponds to the DR condition will be described as an example. When the actual input data corresponds to the DR condition, the quantization range determining unit 42 determines a quantization range of the shift value of the read voltage to be a quantization range RqA corresponding to the DR condition shown in FIG. 9 (step S26).

Next, the parameter setting unit 43 sets a parameter of the quantized neural network 500 based on the quantization range RqA of the shift value of the read voltage determined by the processing of step S26 (step S27). For example, when the quantization range of the shift value of the read voltage is determined to be the quantization range RqA corresponding to the DR condition in the processing of step S26, the parameter setting unit 43 determines to use the basic operation parameter PbA and the quantization parameter PqA as parameters of the quantized neural network 500.

Next, the estimating unit 44 estimates a shift value ΔVr of the read voltage with the quantized neural network using the parameter determined in the processing of step S27 (step S28). For example, the estimating unit 44 inputs the input data generated in the processing of step S24 to the input layer 510 of the quantized neural network 500 while using the basic operation parameter PbA and the quantization parameter PqA determined in the processing of step S27 shown in FIG. 12. Accordingly, the shift value ΔVr of the read voltage is output from the output layer 530 of the quantized neural network 500.

Next, from the shift value ΔVr of the read voltage output from the quantized neural network 500 and the predetermined read voltage nVrB, the voltage setting unit 45 sets the read voltage VrB to “nVrB+ΔVr” (step S29).

Next, the memory controller 1 determines whether or not there is a read voltage of which estimation has not been completed (step S30), and when there is a read voltage of which estimation has not been completed (step S30: YES), the memory controller 1 returns to the processing of step S21. Accordingly, the processing of steps S21 to S30 is repetitively executed until estimation of all read voltages VrA, VrB, VrC, VrD, VrE, VrF, and VrG is completed.

Once the estimation of all read voltages VrA, VrB, VrC, VrD, VrE, VrF, and VrG is completed, the memory controller 1 makes a negative determination in the processing of step S30 (step S30: NO) and ends the processing shown in FIG. 12.

### 1.8 Operation and Effect of Memory System

As described above, the memory system 3 includes the input data acquiring unit 41, the quantization range determining unit 42, the parameter setting unit 43, the estimating unit 44, and the voltage setting unit 45. By having the semiconductor storage device 2 read data using a plurality of read voltages, the input data acquiring unit 41 acquires input data indicating a relationship between the number of on-cells b and the plurality of read voltages. The quantization range determining unit 42 determines a quantization range of a shift value of a read voltage that is estimated by the quantized neural network 500. The parameter setting unit 43 sets parameters Pb and Pq of the quantized neural network 500 based on the quantization range determined by the quantization range determining unit 42. The estimating unit 44 estimates a shift value ΔVr of a read voltage from input data with the quantized neural network 500 using the parameters Pb and Pq set by the parameter setting unit 43. The voltage setting unit 45 sets read voltages VrA, VrB, VrC, VrD, VrE, VrF, and VrG that are used during a read operation of the semiconductor storage device 2 based on the shift value ΔVr of the read voltage.

According to this configuration, since operations of the quantized neural network 500 are performed by integers, the operational load can be reduced. As a result, parameter capacity can be reduced, latency can be reduced, circuit size can be reduced, and the like. In addition, since the quantization range of the shift value of the read voltage is set to an appropriate range corresponding to input data among the three ranges RqA, RqB, and RqC shown in FIG. 9, the operational accuracy of the quantized neural network 500 can also be ensured. As a result, estimation accuracy of read voltage can be secured while reducing the operational burden.

Parameters of the quantized neural network 500 include a basic operation parameter Pb and a quantization parameter Pq. The basic operation parameter Pb includes a weight w of the quantized neural network 500. The quantization parameter Pq includes a quantization scale S and a zero point Z of the quantized neural network 500.

According to this configuration, the quantization range of the quantized neural network 500 can be readily switched according to input data.

The quantization range determining unit 42 determines a quantization range based on a determination as to whether or not the input data satisfies a predetermined boundary condition. As the predetermined boundary condition, the quantization range determining unit 42 uses a plurality of boundary conditions as shown in Expressions f3 and f4 described above.

According to this configuration, the quantization range of the shift value of the read voltage can be set to any of the three ranges RqA, RqB, and RqC shown in FIG. 9.

### 1.9 First Modification

Next, a first modification of the memory system 3 according to the first embodiment will be described.

The boundary conditions for determining which of the three stress conditions the actual input data correspond to are not limited to the conditions shown in Expressions f3 and f4 described above and any condition can be used.

For example, Expression f5 below may be used in place of Expression f3 described above and, at the same time, Expression f6 below may be used in place of Expression f4 described above.

f₀(X)≤0 (f5)

f₁(X)≤0 (f6)

Note that “X” used in Expressions f5 and f6 is defined by Expression f7 below.

X=(X₀, X₁, . . . , X₇) (f7)

In addition, the function f₀ used in Expression f5 can be obtained by, for example, computing a function (kernel function) corresponding to a boundary surface that can demarcate a region where input data corresponding to the DR condition exists from a region where input data corresponding to other conditions exists, using a support vector machine. Furthermore, the function f₀ used in Expression f6 can be obtained by, for example, computing a function corresponding to a boundary surface that can demarcate a region where input data corresponding to the RD condition exists from a region where input data corresponding to the ideal stress condition exists, using a support vector machine.

Even with such a configuration, it is possible to obtain same or similar operations and effects as the memory system 3 according to the first embodiment described above.

### 1.10 Second Modification

Next, a second modification of the memory system according to the first embodiment will be described.

In the first embodiment described above, as shown in FIG. 12, the numbers of difference on-cells X₀ to X₇ contained in the actual input data were used to determine which of the three stress conditions the actual input data corresponded to, and a quantization range of a shift value of a read voltage was set based on the result of the determination.

Alternatively, the quantization range determining unit 42 according to the present modification executes processing of determining a quantization range of a shift value of a read voltage based on an operation value of the first intermediate layer 520A of the quantized neural network 500 as processing of step S25 shown in FIG. 12.

According to this configuration, since the quantization range of the shift value of the read voltage can be determined based on an operation result of the quantized neural network 500, operational accuracy can be increased.

### 2. Second Embodiment

Next, the memory system 3 according to a second embodiment will be described. Hereinafter, a description will be given with a focus on differences from the memory system 3 according to the first embodiment.

### 2.1 Configuration of Memory Controller

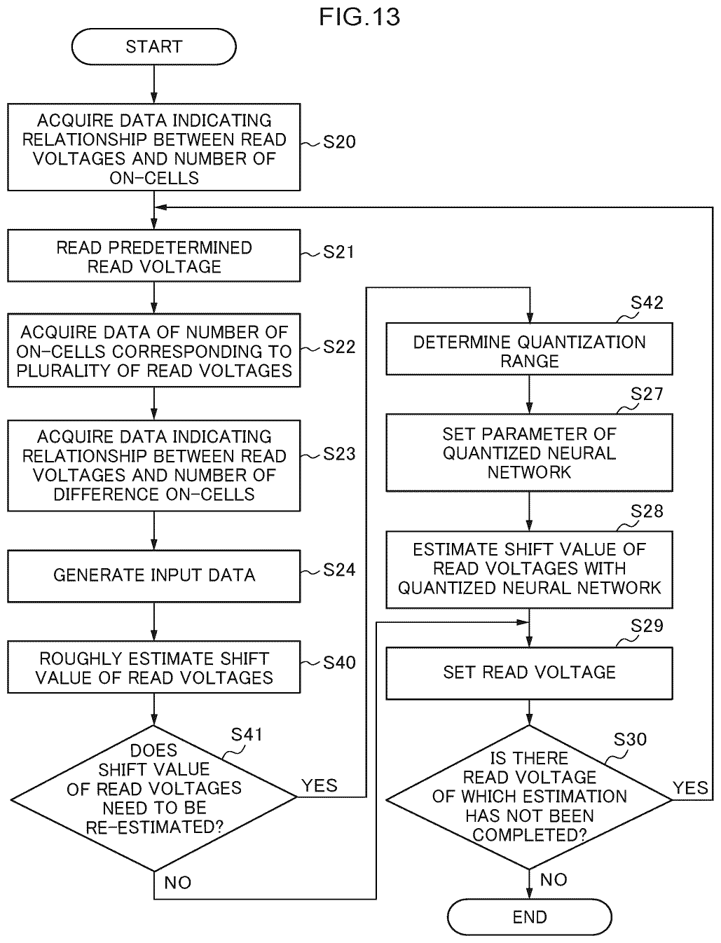

The memory controller 1 according to the present embodiment executes estimation processing of a read voltage by procedures shown in FIG. 13. Note that in the processing shown in FIG. 13, the same processing as that shown in FIG. 12 will be denoted by the same reference signs and redundant descriptions will be omitted.

As shown in FIG. 13, in the memory controller 1 according to the present embodiment, after input data is generated by the input data acquiring unit 41 (step S24), the estimating unit 44 roughly estimates a shift value ΔVr of read voltages using the input data (step S40).

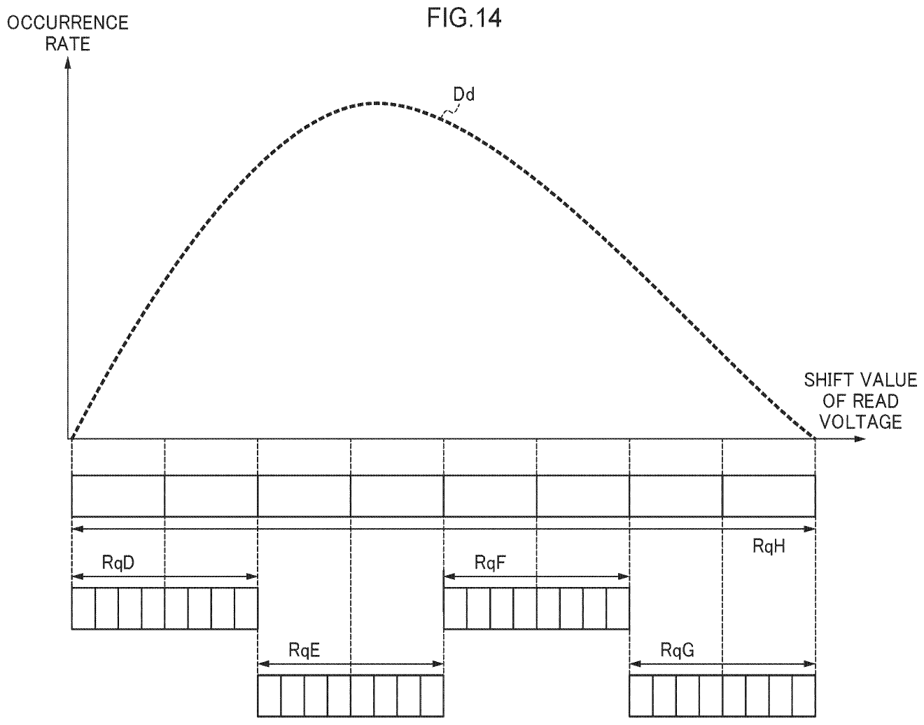

Specifically, as shown in FIG. 14, in the present embodiment, four ranges of RqD, RqE, RqF, RqG, and RqH are set as quantization ranges of the memory cells MT. The quantization range RqH is set so as to include all regions where the shift value ΔVr of the read voltages may possibly be distributed. The other quantization ranges RqD, RqE, RqF, and RqG are set so as to divide the quantization range RqH into four equal parts.

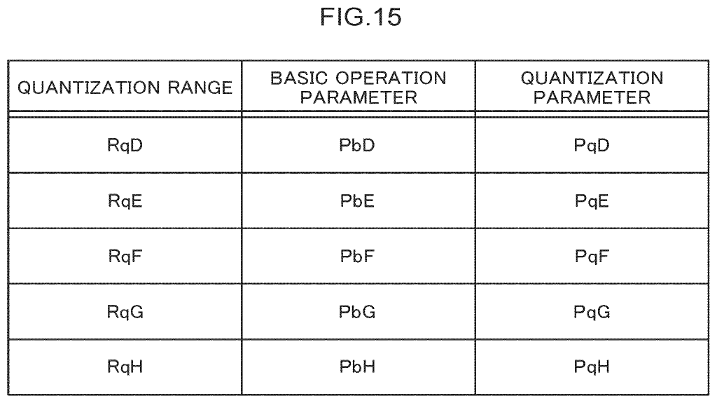

In addition, as shown in FIG. 15, basic operation parameters PbD, PbE, PbF, PbG, and PbH and quantization parameters PqD, PqE, PqF, PqG, and PqH are respectively set regarding each of the quantization ranges RqD, RqE, RqF, RqG, and RqH. The quantization parameters PqD, PqE, PqF, PqG, and PqH according to the present embodiment contain a bit number setting value that enables the number of bits in output data of the quantized neural network 500 to be designated. The bit number setting value of each of the quantization parameters PqD, PqE, PqF, and PqG is set to 3 bits. The bit number setting value of the quantization parameter PqH is set to 2 bits. In other words, in the memory system 3 according to the present embodiment, when using any of the quantization ranges RqD, RqE, RqF, and RqG, the output data of the quantized neural network 500 has an accuracy of 3 bits. In addition, when using the quantization range RqH, the output data of the quantized neural network 500 has an accuracy of 2 bits.

In the processing of step S40 shown in FIG. 13, the estimating unit 44 inputs the input data generated in the processing of step S24 to the input layer 510 of the quantized neural network 500 while using the basic operation parameter PbH and the quantization parameter PqH. Accordingly, an approximate shift value ΔVrA of the read voltage is output with 2-bit accuracy from the output layer 530 of the quantized neural network 500.

Next, the estimating unit 44 determines whether or not the shift value ΔVr of the read voltage needs to be re-estimated (step S41). For example, when the approximate shift value ΔVrA of the read voltage computed in the processing of step S40 indicates a value in any of the quantization ranges RqD and RqE shown in FIG. 14, the estimating unit 44 determines that the shift value ΔVr of the read voltage needs to be re-estimated (step S41: YES). In this case, the quantization range determining unit 42 determines the quantization range of the shift value of the read voltages based on the approximate shift value ΔVrA of the read voltage computed in the processing of step S40 (step S42). For example, when the approximate shift value ΔVrA of the read voltage indicates a value in the quantization range RqD shown in FIG. 14, the quantization range determining unit 42 sets the quantization range of the shift value of the read voltages to RqD. Subsequently, steps S27 and S28 are executed. Accordingly, when the quantization range of the memory cells MT is set to RqD, the shift value ΔVr of the read voltages is computed with 3-bit accuracy or, in other words, higher accuracy in the quantization range RqD shown in FIG. 14. In this manner, when the quantization range of the roughly estimated shift value of a read voltages is any of RqD and RqE, the shift value ΔVr of the read voltages is re-estimated with 3-bit accuracy.

On the other hand, when the approximate shift value ΔVrA of the read voltage in the processing of step S41 indicates a value in any of the quantization ranges RqF and RqG shown in FIG. 14, the quantization range determining unit 42 determines that the shift value ΔVr of the read voltages need not be re-estimated (step S41: NO). In this case, steps S42, S27, and S28 are not executed. Hence, the approximate shift value ΔVrA computed in the processing of step S40 is used as-is as the shift value ΔVr of the read voltages. Therefore, when the quantization range of the roughly estimated shift value of the read voltages is any of RqD and RqE, the shift value ΔVr of the read voltages is estimated with 2-bit accuracy.

When a negative determination is made in the processing of step S41 or after the processing of S28 is executed, processing of steps S29 and S30 is executed.

### 2.2 Operation and Effect of Memory System

The quantization range determining unit 42 according to the present embodiment determines, using an approximate shift value ΔVrA of a read voltage roughly estimated using the quantized neural network 500, a quantization range of a shift value of a read voltage to be estimated by the quantized neural network 500.

According to this configuration, since the quantization range of the shift value of the read voltage can be determined with higher accuracy, the read voltage of memory cells MT can be set with high accuracy.

### 3. Other Embodiments

The present disclosure is not limited to the specific examples described above.

For example, the configuration of the quantized neural network 500 can be optionally changed.

The configuration of the memory system 3 according to each embodiment described above is not limited to a memory system including a NAND flash memory as a semiconductor storage device and is applicable to memory systems including any semiconductor storage device such as an SSD (Solid State Drive) as the semiconductor storage device.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A memory system, comprising:
a nonvolatile memory storing a computer-readable program and a quantized neural network; and
a processor configured to execute the program, wherein
by executing the program, the processor:
acquires, by having a semiconductor storage device read data using a plurality of read voltages, input data indicating a relationship between the number of on-cells being the number of memory cells that were turned on in the semiconductor storage device when the data was read and the plurality of read voltages;
determines a quantization range of a shift value of the read voltages that is estimated by the quantized neural network;
sets a parameter of the quantized neural network based on the quantization range;
estimates a shift value of the read voltages from the input data with the quantized neural network using the parameter; and
computes a read voltage that is used during a read operation of the semiconductor storage device based on the shift value.

2. The memory system according to claim 1, wherein
the parameter includes a weight of the quantized neural network and a quantization parameter.

3. The memory system according to claim 2, wherein
the quantization parameter includes a quantization scale indicating a resolution of a value after quantization and a zero point being an integer value assumed after quantization by a value that had been a real value and zero before quantization.

4. The memory system according to claim 1, wherein
the processor determines the quantization range based on a determination as to whether or not the input data satisfies a predetermined boundary condition.

5. The memory system according to claim 4, wherein
the processor uses the predetermined boundary condition in plurality.

6. The memory system according to claim 1, wherein
the processor sets the quantization range based on the input data.

7. The memory system according to claim 1, wherein
the processor sets the quantization range based on an operation value of an intermediate layer of the quantized neural network.

8. The memory system according to claim 1, wherein
the processor determines, using the shift value roughly estimated using the quantized neural network, a quantization range of a shift value of the read voltages to be estimated by the quantized neural network.

9. A memory system, comprising:
an input data acquiring unit which, by having a semiconductor storage device read data using a plurality of read voltages, acquires input data indicating a relationship between the number of on-cells being the number of memory cells that were turned on in the semiconductor storage device when the data was read and the plurality of read voltages;
a quantization range determining unit which determines a quantization range of a shift value of the read voltages that is estimated by a quantized neural network;
a parameter setting unit which sets a parameter of the quantized neural network based on the quantization range determined by the quantization range determining unit;
an estimating unit which estimates a shift value of the read voltages from the input data with the quantized neural network using the parameter set by the parameter setting unit; and
a voltage setting unit which sets a read voltage that is used during a read operation of the semiconductor storage device based on the shift value.

10. The memory system according to claim 9, wherein
the parameter includes a weight of the quantized neural network and a quantization parameter.

11. The memory system according to claim 10, wherein
the quantization parameter includes a quantization scale indicating a resolution of a value after quantization and a zero point being an integer value assumed after quantization by a value that had been a real value and zero before quantization.

12. The memory system according to claim 9, wherein
the quantization range determining unit determines the quantization range based on a determination as to whether or not the input data satisfies a predetermined boundary condition.

13. The memory system according to claim 12, wherein
the quantization range determining unit uses the predetermined boundary condition in plurality.

14. The memory system according to claim 9, wherein
the quantization range determining unit sets the quantization range based on the input data.

15. The memory system according to claim 9, wherein
the quantization range determining unit sets the quantization range based on an operation value of an intermediate layer of the quantized neural network.

16. The memory system according to claim 9, wherein
the quantization range determining unit determines, using the shift value roughly estimated using the quantized neural network, a quantization range of a shift value of the read voltages to be estimated by the quantized neural network.

17. A method of controlling a memory system including a nonvolatile memory that stores a quantized neural network, the method comprising:
acquiring, by having a semiconductor storage device read data using a plurality of read voltages, input data indicating a relationship between the number of on-cells being the number of memory cells that were turned on in the semiconductor storage device when the data was read and the plurality of read voltages;
determining a quantization range of a shift value of the read voltages that is estimated by the quantized neural network;
setting a parameter of the quantized neural network based on the quantization range;
estimating a shift value of the read voltages from the input data with the quantized neural network using the parameter; and
computing a read voltage that is used during a read operation of the semiconductor storage device based on the shift value.
